(19) United States
(12) Patent Application Publication
(10) Pub. No.: US 2002/0039704 A1
(43) Pub. Date: Apr. 4, 2002

(54) Lithographic and etching process using a hardened photoresist layer

(76) Inventors: Kuen Sane Din, Hsinchu Hsien (TW); Chung Chia Chi, Hsinchu (TW)

Correspondence Address: J.C. Patents, Inc., 4 VENTURE, SUITE 250, Irvine, CA, 92618, US

(21) Appl. No.: 09/737,104

(22) Filed: Dec. 14, 2000

(30) Foreign Application Priority Data
Aug. 18, 2000 (TW) 89116724

(51) Int. Cl. G03F 7/00

(52) U.S. Cl. 430/313; 430/950; 216/41; 216/58

(57) ABSTRACT

The present invention provides a lithography and etching process using a hardened photoresist layer. A material layer is formed over a substrate. An anti-reflective layer is formed over the material layer. A lithography process is performed to form a patterned photoresist layer. A reactive ion etching step is performed to remove the anti-reflective layer exposed by the patterned photoresist layer. At the same time, the patterned photoresist layer is hardened. The material layer is removed using the hardened patterned photoresist layer as a mask. The resolution is improved for lithography and the process window is enlarged for etching process.

### CROSS-REFERENCE TO RELATED APPLICATION

This application claims the priority benefit of Taiwan application serial No. 89116724, filed Aug. 18, 2000.

### BACKGROUND OF THE INVENTION

1. Field of the Invention

The present invention relates to a semiconductor fabrication method. More particularly, the present invention relates to lithography and etching process using a hardened photoresist layer.

2. Description of the Related Art

As the sizes of semiconductor devices decrease, the wavelength of an exposure light source of a lithography and etching process decreases. This, in turn, decreases the depth of focus (DOF). The thickness of a photoresist layer used in a lithography and etching process thereby must be decreased in order to prevent the precision of the lithography and etching process from being affected. However, the current etching process usually uses a plasma anisotropic etching, therefore the photoresist layer is easily eroded during the etching. The photoresist layer, as a result, cannot be overly thin in order to prevent the precision of the lithography and etching process from being affected. In addition, using a commonly-used material in forming the photoresist layer cannot assure the quality of both the lithography process and the etching process.

To solve the aforementioned problem, a thin photoresist layer is usually employed during the lithography process in order to increase the precision of the lithography process. Before the etching process, the photoresist layer is hardened. In another words, the molecules of the photoresist layer are cross-linked. Thus, the photoresist layer is more resistant to the plasma erosion. Conventional methods for hardening the photoresist layer includes hard bake, ultra-violate (Uv) radiation, broad-area electron beam irradiation, and ion implantation. However, conventional methods described above have deficiencies, for example, the hard bake and the ultra-violate irradiation cause distortion of the photoresist layer. In addition, the electron beam irradiation and the ion implantation change the doping characteristics of devices.

### SUMMARY OF THE INVENTION

The present invention provides a lithography and etching process using a hardened photoresist layer. A material layer is formed over a substrate. The material layer can be, for example, a metal layer, a polysilicon layer, a silicon nitride layer, or stacked-gate avalanche-injection metal oxide semiconductor stacked layers. An anti-reflective layer is formed over the material layer. A lithography process is performed to form a patterned photoresist layer. A reactive ion etching step, such as a magnetic-enhanced reactive ion etching, is performed to remove the anti-reflective layer exposed by the patterned photoresist layer. At the same time, the patterned photoresist layer is hardened. Finally, the material layer is removed in a separate etcher by using the hardened patterned photoresist layer as a mask.

The present invention uses the reactive ion etching step to harden the photoresist layer. Thus, in the following steps, the photoresist layer is more resistant to plasma erosion. Thus, the thickness of the photoresist layer can be reduced in order to increase the precision of the photolithography and etching process. In addition, the present invention uses plasma to harden the photoresist layer instead of using hard bake, UV irradiation, electron beam and ion implantation. Thus, no distortion of photoresist layer occurs.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A through 1C are schematic, cross-sectional views illustrating a lithography and etching process using a hardened photoresist layer according to one preferred embodiment of the invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and in the description to refer to the same or like parts.

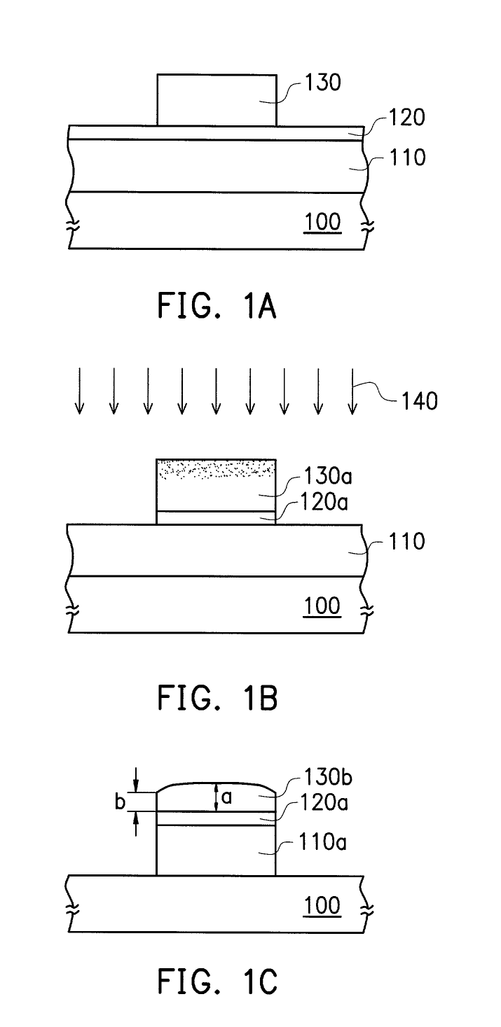

As shown in FIG. 1A, a substrate 100 is provided. A material layer 110 is formed over the substrate 100. The material layer 110 includes either a metal layer, a polysilicon layer, a silicon nitride layer, or SAMOS (stacked-gate avalanche-injection metal oxide semiconductor) stacked layers. An antireflective layer 120, such as a silicon oxy-nitride layer, is formed over the material layer 110. The antireflective layer 120 preferably has a thickness of about 200 angstroms to about 500 angstroms. A lithography process is performed to form a patterned photoresist layer 130, such as a deep ultraviolet (UV) photoresist layer, over the antireflective layer 120.

As shown in FIG. 1B, a reactive ion etching (RIE) step is performed. The antireflective layer 120 exposed by the patterned photoresist layer 130a is removed by plasma 140 to become 120a. At the same time, a surface layer of the photoresist layer 130a is hardened. The surface layer of the photoresist layer 130a is shown as the shaded region in FIG. 1B. According to the experimental results, if the physical bombardment of the plasma is greater, a better hardening effect is achieved. In the present invention, the plasma 140 can be a plasma that is usually used to etch the oxy-nitride layer. The reactive ion etching step can also be performed in the etching station used to etch silicon oxide.

In addition, the parameters of the reactive ion etching step are as follows. The reacting gases include CHF₃, CF₄, Ar, and N₂. The CHF₃ and CF₄ are used to etch the antireflective layer 120. The CHF₃ has a flow rate of about 40 sccm to about 120 sccm. The CF₄ has a flow rate of about 20 sccm to about 80 sccm. The Ar has a flow rate of about 50 sccm to about 200 sccm. The N₂ has a flow rate of about 10 sccm to about 50 sccm. The pressure is about 100 mTorr to about 300 mTorr. The radio frequency (RF) power is about 500 watt to about 2000 watt. The reactive ion etching step is, for example, a magnetic-enhanced reactive ion etching (MERIE) step.

As shown in FIG. 1C, a plasma etching step is performed using the photoresist layer 130a as a mask, which finally becomes 130b. The material layer 110 is removed as exposed by the photoresist layer 130b and the antireflective layer 120a stack. A patterned material layer 110a is formed. During the plasma etching step, the hardened photoresist layer 130b is also consumed, especially, along the periphery of the photoresist layer 130b. A central portion of the photoresist layer 130b has a top thickness a. The periphery portion of the remained photoresist layer 130b has a shoulder thickness b. The shoulder thickness b is smaller than the top thickness a. It should be noted that the shoulder thickness b cannot be too small in order to prevent the underlying antireflective layer 120a from being exposed.

### EXAMPLE

Table 1 lists top thicknesses a and shoulder thicknesses b of the remained photoresist layers 130b after completing the material layer 110a pattern formation that are treated by the RIE step in a separate etch chamber (wafer #1 and wafer #2), and the remained photoresist layer 130b that is not treated by a separate RIE step (wafer #3).

In the example:

1. The material layer 110 is an aluminum copper alloy having a thickness of about 5000 angstroms.

2. The antireflective layer is a silicon oxy-nitride layer having a thickness of about 300 angstroms.

3. The photoresist layer 130 is a deep UV photoresist layer. Before the etching step, the photoresist layer 130 has a thickness of about 7000 angstroms.

4. The patterned photoresist layer 130 includes a plurality of line patterns.

5. The RIE step is a MERIE step. The reacting gases include CHF₃, CF₄, Ar, and N₂.

6. The plasma anisotropic etching is performed to each the material layer 110. The primary components of the reacting gases include Cl₂ and BCl₃.

TABLE 1
Remained Photoresist thickness

| | | | Flow | Flow | Flow | Flow | Top | Shoulder |
|---|---|---|---|---|---|---|---|---|
| Wafer | | RF | rate of | rate of | rate of | rate of | thickness | thickness |
| number | Pressure | Power | CHF₃ | CF₄ | N₂ | Ar | a | b |
| # | (mTorr) | (W) | (sccm) | (sccm) | (sccm) | (sccm) | (angstroms) | (angstroms) |
| 1 | 150 | 1100 | 80 | 40 | 20 | 180 | 2686 | 1857 |
| 2 | 150 | 1100 | 40 | 20 | 20 | 180 | 2200 | 1543 |

| | | | |
|---|---|---|---|
| 3 | Without RIE Step | 1600 | 771 |

As shown in Table 1, compared to the remained photoresist layer 130b that is not hardened by the RIE step, after the metal line etching step, the remained photoresist layer 130b hardened by the RIE step has a larger top thickness a and a larger shoulder thickness b. That is, the photoresist layer 130a treated by RIE is more resistant to plasma erosion. The RIE step can be used to harden the photoresist layer 130a.

As stated above, the present invention uses the RIE step to harden the deep UV photoresist layer 130a. Thus, in the following material layer etch step, the photoresist layer 130a is more resistant to plasma erosion. Thus, the thickness of the photoresist layer 130 can be reduced in order to increase the resolution of the photolithography. The process window can be enlarged through this photoresist hardening method. In addition, the present invention uses plasma to harden the photoresist layer 130a instead of using hard bake, UV irradiation, electron beam and ion implantation. Thus, no distortion of photoresist layer occurs.

It will be apparent to those skilled in the art that various modifications and variations can be made to the structure and the method of the present invention without departing from the scope or spirit of the invention. In view of the foregoing, it is intended that the present invention cover modifications and variations of this invention provided they fall within the scope of the following claims and their equivalents.

What is claimed is:

1. A lithography and etching process using a hardened photoresist layer, comprising:
forming a material layer over a substrate;
forming an antireflective layer over the material layer;
performing a lithography process to form a patterned photoresist layer
performing a reactive ion etching step to remove the anti-reflective layer exposed by the patterned photoresist layer and harden the patterned photoresist layer simultaneously; and
removing the material layer using a hardened patterned photoresist layer as a mask.

2. The method of claim 1, wherein the material layer is a metal layer, a polysilicon layer, a silicon nitride layer, or stacked-gate avalanche-injection metal oxide semiconductor stacked (SAMOS) layers.

3. The method of claim 1, wherein forming the antireflective layer comprises forming a silicon oxy-nitride layer.

4. The method of claim 1, wherein forming the patterned photoresist layer comprises forming a deep ultra-violet photoresist layer.

5. The method of claim 1, wherein performing the reactive ion etching step comprises performing a magnetic-enhanced reactive ion etching.

6. The method of claim 1, wherein the reactive ion etching is performed in a station used for etching a silicon oxide.

7. The method of claim 1, wherein the reactive ion etching uses reacting gases including CHF₃, CF₄, Ar, and N₂.

8. The method of claim 7, wherein the CHF₃ has a flow rate of about 40 sccm to about 120 sccm.

9. The method of claim 7, wherein the CF₄ has a flow rate of about 20 sccm to about 80 sccm.

10. The method of claim 7, wherein the Ar has a flow rate of about 50 sccm to about 200 sccm.

11. The method of claim 7, wherein the N₂ has a flow rate of about 10 sccm to about 50 sccm.

12. The method of claim 1, wherein the reactive ion etching step has a pressure of about 100 mTorr to about 300 mTorr.

13. The method of claim 1, wherein the reactive etching step has a radio frequency (RF) power of about 500 W to about 2000 W.

14. A lithography and etching process using a hardened photoresist layer, comprising:
forming a silicon oxy-nitride antireflective layer over the material layer;
forming a patterned deep ultraviolet photoresist layer over the silicon oxy-nitride antireflective layer;
etching the silicon oxy-nitride antireflective layer exposed by the patterned deep ultraviolet photoresist layer and hardening the deep ultraviolet photoresist layer simultaneously; and
using a hardened deep ultraviolet photoresist layer as a mask to remove the material layer.

15. The method of claim 14, wherein the material layer is a metal layer, a polysilicon layer, a silicon nitride layer, or stacked-gate avalanche-injection metal oxide semiconductor stacked (SAMOS) layers.

16. The method of claim 14, wherein etching the silicon oxy-nitride antireflective layer comprises performing a reactive ion etching.

17. The method of claim 14, wherein the reactive ion etching comprises a magnetic-enhanced reactive ion etching.

18. The method of claim 17, wherein the reactive ion etching is performed in a station used for etching a silicon oxide.

19. The method of claim 1, wherein the reactive ion etching has reacting gases including CHF₃, CF₄, Ar, and N₂.

20. The method of claim 19, wherein the reactive ion etching comprises:
a flow rate of the CHF₃ is about 40 sccm to about 120 sccm;
a flow rate of the CF₄ is about 20 sccm to about 80 sccm;
a flow rate of the Ar about 50 sccm to about 200 sccm;
a flow rate of the N₂ is about 10 sccm to about 50 sccm;
a pressure is about 100 mTorr to about 300 mTorr; and
a RF power is about 500 W to about 2000 W.
